(19) United States
(12) Patent Application Publication
(10) Pub. No.: US 2025/0318391 A1
(43) Pub. Date: Oct. 9, 2025

(54) DISPLAY DEVICE, METHOD OF MANUFACTURING THE SAME, AND ELECTRONIC DEVICE

(71) Applicant: Samsung Display Co., LTD., Yongin-si (KR)

(72) Inventor: Soo Hyun PARK, Yongin-si (KR)

(73) Assignee: Samsung Display Co., LTD., Yongin-si (KR)

(21) Appl. No.: 19/077,611

(22) Filed: Mar. 12, 2025

(30) Foreign Application Priority Data
Apr. 9, 2024 (KR) 10-2024-0047914

(51) Int. Cl. H10K 59/35; H10K 50/115; H10K 59/12; H10K 59/122; H10K 71/13

(52) U.S. Cl. CPC H10K 59/353; H10K 50/115; H10K 59/1201; H10K 59/122; H10K 71/135

(57) ABSTRACT

According to the disclosure, a display device includes organic light emitting elements each including an organic light emitting layer, and quantum dot light emitting elements each including a quantum dot light emitting layer, the organic light emitting elements and the quantum dot light emitting elements are positioned in a same layer, and each of the quantum dot light emitting elements is surrounded by adjacent organic light emitting elements.

### CROSS REFERENCE TO RELATED APPLICATION(S)

This application claims priority to Korean Patent Application No. 10-2024-0047914 under 35 U.S.C. § 119, filed on Apr. 9, 2024, the entire contents of which are incorporated herein by reference.

### BACKGROUND

### 1. Technical Field

Embodiments relate to a display device, a method of manufacturing the display device, and an electronic device.

### 2. Description of the Related Art

As information technology develops, importance of a display device, which is a connection medium between a user and information, has been highlighted. In response to this, a use of a display device such as a liquid crystal display device and an organic light emitting display device is increasing.

The display device may include light emitting layers formed of various materials. Due to variety of materials, particles of the light emitting layer may be positioned unregularly or oriented in a specific direction. Thus, a problem that display quality of the display device is deteriorated exists.

### SUMMARY

Embodiments provide a display device, a method of manufacturing the display device, and an electronic device in which particles of light emitting layers may be positioned uniformly even though the light emitting layers formed of various materials are included.

However, embodiments are not limited to those set forth herein. The above and other embodiments will become more apparent to one of ordinary skill in the art to which the disclosure pertains by referencing the detailed description of the disclosure given below.

According to an embodiment of the disclosure, a display device may include organic light emitting elements each including an organic light emitting layer, and quantum dot light emitting elements each including a quantum dot light emitting layer, the organic light emitting elements and the quantum dot light emitting elements are positioned in a same layer, and each of the quantum dot light emitting elements may be surrounded by adjacent organic light emitting elements.

Distances between each of the quantum dot light emitting elements and the adjacent organic light emitting elements may be shorter than distances between each of the quantum dot light emitting elements and adjacent quantum dot light emitting elements.

The quantum dot light emitting elements may include first quantum dot light emitting elements that emit light of a first color and second quantum dot light emitting elements that emit light of a second color, the organic light emitting elements may emit light of a third color, and the first color, the second color, and the third color may be different colors from each other.

A number of quantum dot light emitting elements and a number of organic light emitting elements may be same as each other.

Each of the organic light emitting elements and each of the quantum dot light emitting elements may include independent anode electrodes, and the organic light emitting elements and the quantum dot light emitting elements may include a common cathode electrode.

The display device may further include a bank including openings exposing the anode electrodes.

The quantum dot light emitting layer may include a quantum dot compound, and the organic light emitting layer may include an organic material.

According to an embodiment of the disclosure, a method of manufacturing a display device may include forming anode electrodes of organic light emitting elements and quantum dot light emitting elements, forming a bank including openings exposing the anode electrodes, forming light emitting members in each of the openings, and forming a cathode electrode to cover the light emitting members, each of the light emitting members of the organic light emitting elements may include an organic light emitting layer, each of the light emitting members of the quantum dot light emitting elements may include a quantum dot light emitting layer, and each of the quantum dot light emitting elements may be surrounded by adjacent organic light emitting elements.

The forming of the light emitting members may include discharging an organic ink corresponding to the organic light emitting layer, and discharging a quantum dot ink corresponding to the quantum dot light emitting layer, and a solvent amount of the organic ink may be greater than or equal to a solvent amount of the quantum dot ink.

The forming of the light emitting members may further include starting to dry the organic ink and the quantum dot ink simultaneously after discharge of the organic ink and the quantum dot ink is ended.

After drying of the quantum dot ink is completed, drying of the organic ink may be completed.

Distances between each of the quantum dot light emitting elements and the adjacent organic light emitting elements may be shorter than distances between each of the quantum dot light emitting elements and adjacent quantum dot light emitting elements.

The quantum dot light emitting elements may include first quantum dot light emitting elements that emit light of a first color and second quantum dot light emitting elements that emit light of a second color, the organic light emitting elements may emit light of a third color, and the first color, the second color, and the third color are different colors from each other.

A number of quantum dot light emitting elements and a number of organic light emitting elements may be same as each other.

According to an embodiment of the disclosure, a method of manufacturing a display device may include forming anode electrodes of organic light emitting elements and quantum dot light emitting elements, forming a bank including openings exposing the anode electrodes, forming light emitting members in each of the openings, and forming a cathode electrode to cover the light emitting members, each of the light emitting members of the organic light emitting elements may include an organic light emitting layer, each of the light emitting members of the quantum dot light emitting elements may include a quantum dot light emitting layer, the forming of the light emitting members may include discharging an organic ink corresponding to the organic light emitting layer, and discharging a quantum dot ink corresponding to the quantum dot light emitting layer, and a solvent amount of the organic ink is greater than or equal to a solvent amount of the quantum dot ink.

Each of the quantum dot light emitting elements may be surrounded by adjacent organic light emitting elements.

The forming of the light emitting members may further include starting to dry the organic ink and the quantum dot ink simultaneously after discharge of the organic ink and the quantum dot ink is ended.

After drying of the quantum dot ink is completed, drying of the organic ink may be completed.

Distances between each of the quantum dot light emitting elements and the adjacent organic light emitting elements may be shorter than distances between each of the quantum dot light emitting elements and adjacent quantum dot light emitting elements.

The quantum dot light emitting elements may include first quantum dot light emitting elements that emit light of a first color and second quantum dot light emitting elements that emit light of a second color, the organic light emitting elements may emit light of a third color, and the first color, the second color, and the third color may be different colors from each other.

According to an embodiment of the disclosure, an electronic device may include: a processor to provide input image data; and a display device to display an image based on the input image data. The display device may include: organic light emitting elements each including an organic light emitting layer; and quantum dot light emitting elements each including a quantum dot light emitting layer. The organic light emitting elements and the quantum dot light emitting elements may be positioned in a same layer. Each of the quantum dot light emitting elements may be surrounded by adjacent organic light emitting elements.

According to a display device, a method of manufacturing the display device, and an electronic device, particles of light emitting layers may be positioned uniformly even though the light emitting layers formed of various materials are included.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to an embodiment;

FIGS. 2 and 3 are schematic plan views illustrating a disposition of a light emitting layer according to an embodiment;

FIG. 4 is a schematic diagram illustrating a disposition of a light emitting layer according to another embodiment;

FIG. 5 is a schematic cross-sectional view taken along line I-I′ of FIG. 2 or FIG. 3;

FIGS. 6 to 11 are schematic diagrams illustrating a method of manufacturing a display device according to an embodiment;

FIG. 12 is a schematic block diagram illustrating an electronic device including a display device in accordance with an embodiment;

FIG. 13 is a schematic diagram illustrating an example where the electronic device of FIG. 12 is a smartphone; and

FIG. 14 is a schematic diagram illustrating an example where the electronic device of FIG. 12 is a tablet computer.

### DETAILED DESCRIPTION OF THE EMBODIMENT

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

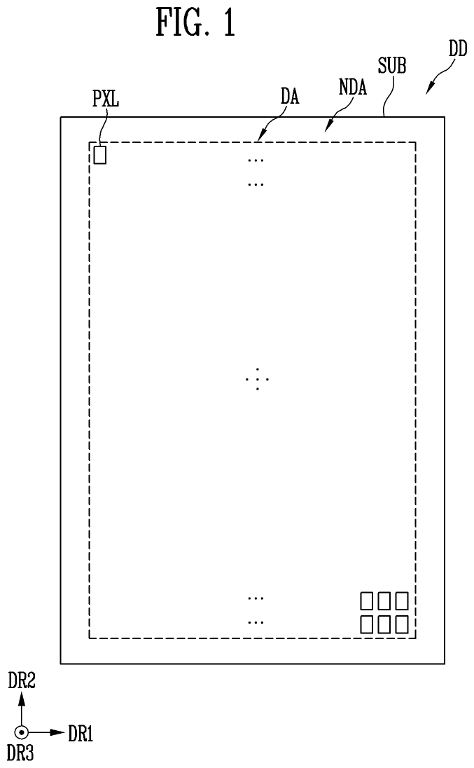

FIG. 1 is a schematic plan view illustrating a display device according to an embodiment.

Referring to FIG. 1, the display device DD may include a substrate SUB and pixels PXL disposed on the substrate SUB. For example, the display device DD may further include a driving circuit unit (for example, a scan driver and a data driver) for driving the pixels PXL, lines, and pads.

The display device DD (or the substrate SUB) may include a display area DA and a non-display area NDA. The non-display area NDA may refer to an area other than the display area DA. The non-display area NDA may surround at least a portion of the display area DA.

The substrate SUB may form a base surface of the display device DD. The substrate SUB may be a rigid substrate or film or a flexible substrate or film. For example, the substrate SUB may include a glass material. In another example, the substrate SUB may include a silicon material. In another example, the substrate SUB may include polyimide. However, embodiments are not limited thereto.

The display area DA may refer to an area where the pixels PXL are disposed. The non-display area NDA may refer to an area where the pixels PXL are not disposed. The driving circuit units, the lines, and the pads connected to the pixels PXL of the display area DA may be disposed in the non-display area NDA.

The pixels PXL may be disposed on a plane defined by a first direction DR1 and a second direction DR2. A display direction of the pixels PXL may be in a third direction DR3. The first direction DR1, the second direction DR2, and the third direction DR3 may be perpendicular to each other.

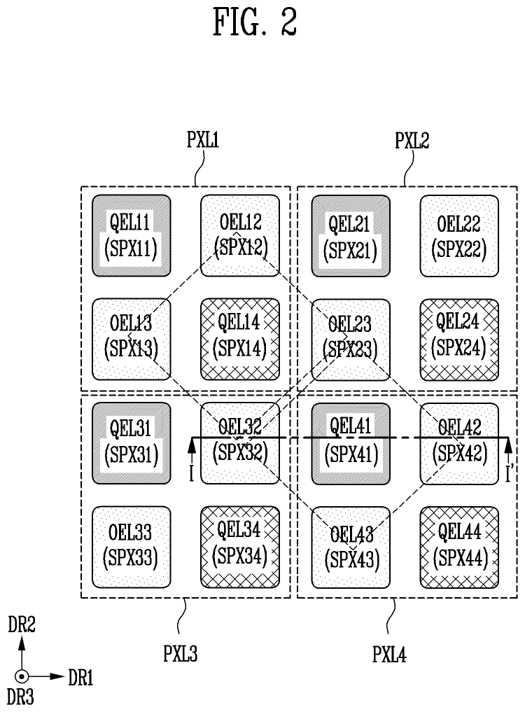

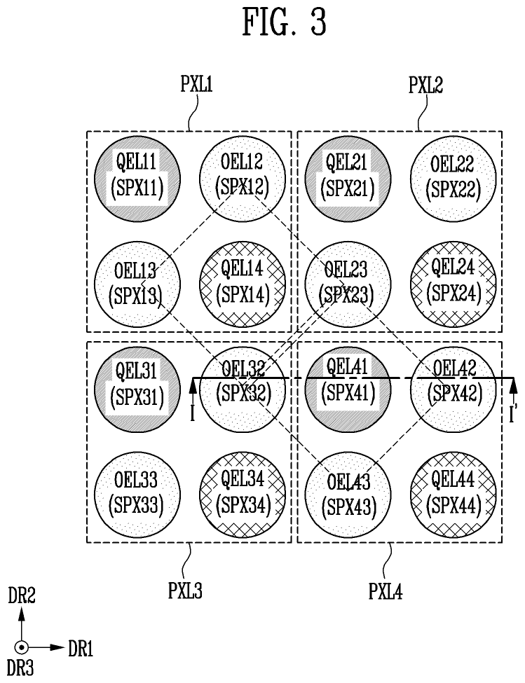

FIGS. 2 and 3 are schematic plan views illustrating a disposition of a light emitting layer according to an embodiment.

Referring to FIGS. 2 and 3, each of the pixels PXL1, PXL2, PXL3, PXL4, etc., may include sub-pixels. For example, the pixel PXL1 may include sub-pixels SPX11, SPX12, SPX13, and SPX14, the pixel PXL2 may include sub-pixels SPX21, SPX22, SPX23, and SPX24, the pixel PXL3 may include sub-pixels SPX31, SPX32, SPX33, and SPX34, and the pixel PXL4 may include sub-pixels SPX41, SPX42, SPX43, and SPX44.

Each of the sub-pixels SPX11 to SPX44 may include a sub-pixel circuit and a light emitting element. For example, the sub-pixel circuit may be connected to a data line and a scan line, and may store a data voltage applied to the data line when a scan signal is applied to the scan line. For example, by transmitting a driving current corresponding to the data voltage to the light emitting element, the light emitting element may emit light at a selected luminance.

The first sub-pixels SPX11, SPX21, SPX31, SPX41, etc., may include first quantum dot light emitting elements that emit light of a first color. The first quantum dot light emitting elements may include first quantum dot light emitting layers QEL11, QEL21, QEL31, QEL41, etc. The second sub-pixels SPX14, SPX24, SPX34, SPX44, etc., may include second quantum dot light emitting elements that emit light of a second color. The second quantum dot light emitting elements may include second quantum dot light emitting layers QEL14, QEL24, QEL34, QEL44, etc. The third sub-pixels SPX12, SPX13, SPX22, SPX23, SPX32, SPX33, SPX42, SPX43, etc., may include organic light emitting elements that emit light of a third color. The organic light emitting elements may include organic light emitting layers OEL12, OEL13, OEL22, OEL23, OEL32, OEL33, OEL42, OEL43, etc.

The first color, the second color, and the third color may be different colors from each other. For example, the first color may be one of red, green, and blue, the second color may be one other than the first color among red, green, and blue, and the third color may be one other than the first color and the second color among red, green, and blue. For example, magenta, cyan, and yellow may be used instead of red, green, and blue as the first to third colors.

The number of quantum dot light emitting layers and the number of organic light emitting layers included in each of the pixels PXL1, PXL2, PXL3, PXL4, etc., may be the same. For example, each of the pixels PXL1, PXL2, PXL3, PXL4, etc., may include two quantum dot light emitting layers and two organic light emitting layers. For example, in the display device DD, the number of quantum dot light emitting elements (e.g., QEL11 to QEL44) and the number of organic light emitting elements may be the same as each other.

In another embodiment, when the number and a disposition of the quantum dot light emitting layers and the organic light emitting layers included in each pixel are the same as those of FIG. 2 or FIG. 3, colors of the quantum dot light emitting elements (e.g., QEL11 to QEL44) and organic light emitting elements may be variously configured or implemented. For example, two quantum dot light emitting layers included in each pixel may not necessarily have to be of different colors from each other. For example, two organic light emitting layers included in each pixel do not necessarily have to be of the same color. For example, the two quantum dot light emitting layers included in each pixel may be formed to emit light in the first color, and the two organic light emitting layers may emit light in the second color and the third color, respectively.

Referring to FIG. 2, the quantum dot light emitting layers QEL11 to QEL44 and the organic light emitting layers OEL12 to OEL43 may have a quadrangular shape. Referring to FIG. 3, the quantum dot light emitting layers QEL11 to QEL44 and the organic light emitting layers OEL12 to OEL43 may have a circular shape. In another embodiment, the quantum dot light emitting layers QEL11 to QEL44 and the organic light emitting layers OEL12 to OEL43 may have various shapes, such as an elliptical shape, a triangular shape, a pentagonal shape, or a hexagonal shape. For example, the quantum dot light emitting layers QEL11 to QEL44 and the organic light emitting layers OEL12 to OEL43 may have the same area and shape.

According to an embodiment, each of the quantum dot light emitting elements (e.g., QEL11 to QEL44) may be surrounded by adjacent organic light emitting elements (e.g., OEL12 to OEL43). For example, each of the quantum dot light emitting layers QEL11 to QEL44 of the quantum dot light emitting elements (e.g., QEL11 to QEL44) may be surrounded by organic light emitting layers (e.g., OEL12, OEL13, OEL22, OEL23, OEL32, OEL33, OEL42, OEL43, etc.) of adjacent organic light emitting elements (e.g., OEL12 to OEL43). For example, the second quantum dot light emitting layer QEL14 may be surrounded by adjacent organic light emitting layers OEL12, OEL13, OEL23, and OEL32. For example, the first quantum dot light emitting layer QEL41 may be surrounded by adjacent organic light emitting layers OEL23, OEL32, OEL42, and OEL43.

Distances between each of the quantum dot light emitting elements (e.g., QEL11 to QEL44) and adjacent organic light emitting elements (e.g., OEL12 to OEL43) may be shorter than distances between each of the quantum dot light emitting elements (e.g., QEL11 to QEL44) and adjacent quantum dot light emitting elements (e.g., QEL11 to QEL44). For example, distances between the second quantum dot light emitting layer QEL14 and adjacent organic light emitting layers OEL12, OEL13, OEL23, and OEL32 may be shorter than distances between the second quantum dot light emitting layer QEL14 and adjacent quantum dot light emitting layers QEL11, QE21, QEL31, and QEL41. The adjacent organic light emitting layers OEL12, OEL13, OEL23, and OEL32 may be positioned in the first direction DR1 or the second direction DR2 from the second quantum dot light emitting layer QEL14, and the adjacent quantum dot light emitting layers QEL11, QE21, QEL31, and QEL41 may be positioned in a diagonal direction from the second quantum dot light emitting layer QEL14. For example, the distance may refer to a distance between center points of the organic light emitting layers (e.g., OEL12, OEL13, OEL23, and OEL32).

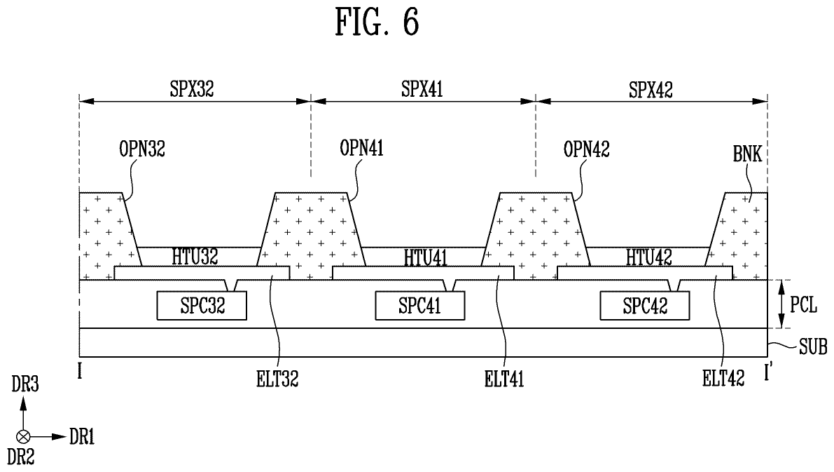

According to the structure (or formation) of the embodiment, an evaporation speed of the quantum dot light emitting layers QEL11 to QEL44 may be affected by an evaporation speed of adjacent organic light emitting layers. This is described with reference to a manufacturing method of FIGS. 6 to 11.

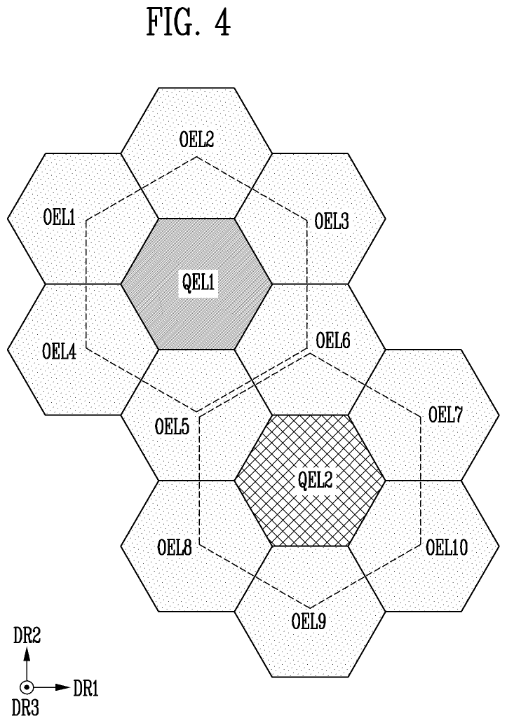

FIG. 4 is a schematic diagram illustrating a disposition of a light emitting layer according to another embodiment.

Referring to FIG. 4, quantum dot light emitting elements QEL1, QEL2, etc., and organic light emitting elements OEL1, OEL2, OEL3, OEL4, OEL5, OEL6, OEL7, OEL8, OEL9, OEL10, etc., may have a regular hexagonal shape. Thus, a wasted space (e.g., a space that is not covered by the light emitting layer) of the display area DA may be minimized.

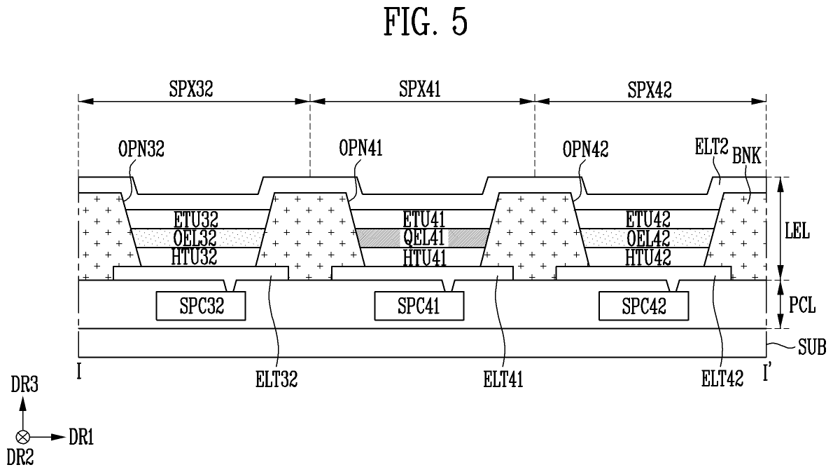

FIG. 5 is a schematic cross-sectional view taken along line I-I′ of FIG. 2 or FIG. 3.

The display device DD may include a substrate SUB, a pixel circuit layer PCL, and a light emitting element layer LEL.

The pixel circuit layer PCL may be positioned on the substrate SUB. The pixel circuit layer PCL may include sub-pixel circuits SPC32, SPC41, SPC42, etc., corresponding to respective sub-pixels SPX32, SPX41, SPX42, etc. For example, each of the sub-pixel circuits SPC32, SPC41, SPC42, etc., may include at least one transistor and at least one capacitor. The pixel circuit layer PCL may include conductive layers and insulating layers, and patterns of the conductive layers may be formed integrally or connected to each other through a contact hole of the insulating layers to configure a transistor, a capacitor, or lines. For example, the sub-pixel circuit may be connected to the data line and the scan line, and may store the data voltage applied to the data line when the scan signal is applied to the scan line. For example, a driving current corresponding to the data voltage may be transmitted to the light emitting element, and thus the light emitting element may emit light at a selected luminance.

The light emitting element layer LEL may be positioned on the pixel circuit layer PCL. The light emitting element layer LEL may include anode electrodes ELT32, ELT41, ELT42, etc., a bank BNK, light emitting structures (or light emitting members), and a cathode electrode ELT2. The light emitting element of each of the sub-pixels SPX32, SPX41, SPX42, etc., may include a corresponding anode electrode, light emitting structure, and cathode electrode.

The anode electrodes ELT32, ELT41, ELT42, etc., may be positioned on the pixel circuit layer PCL. The anode electrodes ELT32, ELT41, ELT42, etc., may be connected to the corresponding sub-pixel circuits SPC32, SPC41, SPC42, etc., through contact holes of the pixel circuit layer PCL. Each of the organic light emitting elements and each of the quantum dot light emitting elements QEL11 to QEL44 may include independent anode electrodes ELT32, ELT41, ELT42, etc.

The anode electrodes ELT32, ELT41, ELT42, etc., may include various conductive materials according to an embodiment. For example, the anode electrodes ELT32, ELT41, ELT42, etc., may include one or more of a group of gold (Au), silver (Ag), aluminum (Al), molybdenum (Mo), chromium (Cr), titanium (Ti), nickel (Ni), neodymium (Nd), copper (Cu), and platinum (Pt), and according to an embodiment, the anode electrodes ELT32, ELT41, ELT42, etc., may include a transparent conductive material.

The bank BNK may be disposed on the pixel circuit layer PCL and the anode electrodes ELT32, ELT41, ELT42, etc. The bank BNK may include openings OPN32, OPN41, and OPN42 exposing the anode electrodes ELT32, ELT41, ELT42, etc. The openings OPN32, OPN41, and OPN42 may be an area where an ink may be received when an inkjet printing process for manufacturing the quantum dot light emitting layers QEL41, etc., and the organic light emitting layers OEL32, OEL42, etc., is performed.

The bank BNK may include an organic material. For example, the bank BNK may include one or more of a group of acrylic resin, epoxy resin, phenol resin, polyamide resin, and polyimide resin. However, embodiments are not limited thereto.

The light emitting structures (or light emitting members) may include corresponding hole transport layers, light emitting layers, and electron transport layers. For example, the light emitting structure of the third sub-pixel SPX32 may include a hole transport layer HTU32, an organic light emitting layer OEL32, and an electron transport layer ETU32. The light emitting structure of the first sub-pixel SPX41 may include a hole transport layer HTU41, a first quantum dot light emitting layer QEL41, and an electron transport layer ETU41. The light emitting structure of the third sub-pixel SPX42 may include a hole transport layer HTU42, an organic light emitting layer OEL42, and an electron transport layer ETU42.

In an embodiment, the light emitting structures (or light emitting members) may be positioned inside the corresponding openings OPN32, OPN41, OPN42, etc. For example, the hole transport layers HTU32, HTU41, HTU42, etc., the emitting layers OEL32, QEL41, OEL42, etc., and the electron transport layers ETU32, ETU41, ETU42, etc., may be individually printed inside the openings OPN32, OPN41, OPN42, etc. For example, the hole transport layers HTU32, HTU41, HTU42, etc., may be formed to be separated from each other. For example, the electron transport layers ETU32, ETU41, ETU42, etc., may be formed separately from each other.

In another embodiment, the light emitting structures (or light emitting members) may be formed to include at least one common layer. For example, at least one common layer may cover an inside of the openings OPN32, OPN41, OPN42, etc., and an upper surface of the bank BNK. For example, the hole transport layers HTU32, HTU41, HTU42, etc., may be formed of one body of common layer covering the sub-pixels SPX32, SPX41, SPX42, etc. For example, the electron transport layers ETU32, ETU41, ETU42, etc., may be formed of one body of common layer covering the sub-pixels SPX32, SPX41, SPX42, etc.

The hole transport layers HTU32, HTU41, HTU42, etc., may be formed to transport a hole. According to an embodiment, the hole transport layers HTU32, HTU41, HTU42, etc., may include various hole transport organic materials and may further include a p-dopant, a known spin-coated polymer, and the like. The light emitting structure may further include a hole injection layer, and according to an embodiment, may further include a light emitting auxiliary layer and an electron blocking layer.

The hole injection layer may be a layer that performs or improves a hole injection function from the anode electrode to another adjacent layer. The hole transport layer may be a layer that provides a provided hole to the light emitting layer. The light emitting auxiliary layer may be a layer that compensates for a resonance distance based on a wavelength of light provided by the light emitting layer. The electron blocking layer may be a layer that prevents an electron from being injected from the electron transport layer to reduce the number of carriers (for example, holes or electrons) leaving the light emitting layer.

The organic light emitting layer (e.g., OEL12, OEL13, OEL23, or OEL32) may generate light based on the input driving current. The light emitting layers OEL32, QEL41, OEL42, etc., may be disposed between the hole transport layers HTU32, HTU41, HTU42, etc., and the electron transport layers ETU32, ETU41, ETU42, etc.

The organic light emitting layer (e.g., OEL12, OEL13, OEL23, or OEL32) may include a material that emits light of one color. The organic light emitting layer (e.g., OEL12, OEL13, OEL23, or OEL32) may include at least some different materials for each of the sub-pixels. For example, the light emitting layers OEL32, QEL41, OEL42, etc., may include the organic light emitting layers OEL32, OEL42, etc., and the quantum dot light emitting layers QEL41, etc. Accordingly, the display device DD may form a hybrid light emitting structure (or hybrid light emitting structure) including two or more types of different materials.

The organic light emitting layers OEL32, OEL42, etc., may include an organic material. The organic light emitting layers OEL32, OEL42, etc., may include a host and a dopant. The host may be a light emitting material that captures carriers (electrons and holes) for light generation, and may induce an exciton to be efficiently generated. The dopant may include a phosphorescent dopant or a fluorescent dopant. According to an embodiment, an example of the dopant is not limited thereto. According to an embodiment, the dopant may include an organic material, and may include a metal complex, and the like.

The quantum dot light emitting layers QEL41, etc., may include a quantum dot compound. For example, the quantum dot compound may include a crystal of a semiconductor compound. For example, the quantum dot compound may include a group III-VI semiconductor compound; a group II-VI semiconductor compound; a group III-V semiconductor compound; a group IV-VI semiconductor compound; a group IV element or compound; and a semiconductor material selected from a group consisting of a combination thereof. However, embodiments are not limited thereto. A diameter of the quantum dot compound is not limited, and since an energy band gap may be adjusted by adjusting a size of the quantum dot compound, each of the quantum dot light emitting layers QEL41, etc., may be formed to emit light of one color.

According to an embodiment, a thickness of the quantum dot light emitting layers QEL41, etc., and a thickness of the organic light emitting layers OEL32, OEL42, etc., may be substantially similar to each other. For example, the thickness of the quantum dot light emitting layers QEL41, etc., and the thickness of the organic light emitting layers OEL32, OEL42, etc., may be the same as each other. For example, the thickness may refer to a length in the third direction DR3.

The electron transport layers ETU32, ETU41, ETU42, etc., may be formed to transport an electron. According to an embodiment, the electron transport layers ETU32, ETU41, ETU42, etc., may include various electron transport materials. For example, the electron transport layers ETU32, ETU41, ETU42, etc., may include a metal-free organic material, and may include metal-containing organic material or various metal materials (for example, an alkaline earth metal, a rare earth metal, and/or the like). The light emitting structure may further include an electron injection layer, and according to an embodiment, may further include an electron buffer layer, a hole blocking layer, and the like.

The electron injection layer may be a layer that performs or improves an electron injection function from the cathode electrode ELT2 to another adjacent layer. The electron transport layer may be a layer that provides a provided electron to the light emitting layer. The hole blocking layer may be a layer that prevents a hole from being injected from the hole transport layer to reduce the number of a carrier leaving the light emitting layer.

The cathode electrode ELT2 may be disposed on the light emitting structures (or light emitting members) and the banks BNK. The organic light emitting elements and the quantum dot light emitting elements QEL11 to QEL44 of the sub-pixels SPX32, SPX41, SPX42, etc., may include a common cathode electrode ELT2.

The cathode electrode ELT2 may include transparent conductive materials such as indium tin oxide (ITO), indium zinc oxide (IZO), zinc oxide (ZnOₓ), indium gallium zinc oxide (IGZO), and indium tin zinc oxide (ITZO). However, embodiments are not limited thereto. For example, the cathode electrode ELT2 may include a conductive material that is somewhat reflective.

FIGS. 6 to 11 are schematic diagrams illustrating a method of manufacturing a display device according to an embodiment.

Referring to FIG. 6, first, the anode electrodes ELT32, ELT41, ELT42, etc., of the organic light emitting elements and the quantum dot light emitting elements QEL11 to QEL44 may be formed. For example, the bank BNK including the openings OPN32, OPN41, and OPN42 exposing the anode electrodes ELT32, ELT41, ELT42, etc., may be formed.

For example, the light emitting structures (or light emitting members) may be formed in each of the openings OPN32, OPN41, and OPN42. In FIG. 6, a state in which the hole transport layers HTU32, HTU41, HTU42, etc., of the light emitting structures (or light emitting members) are formed is shown as an example. According to an embodiment, the hole transport layers HTU32, HTU41, HTU42, etc., may be formed by various methods such as vacuum deposition, spin coating, casting, Langmuir-Blodgett (LB), inkjet printing, laser printing, and laser induced thermal imaging (LITI).

For example, the organic light emitting layers OEL32, OEL42, etc., and the quantum dot light emitting layers QEL41, etc., may be required to be formed. Organic inks may be used to form the organic light emitting layers OEL32, OEL42, etc. Quantum dot inks may be used to form the quantum dot light emitting layers QEL41, etc. The organic inks may include an organic material and a solvent. The quantum dot inks may include a quantum dot compound and a solvent. For example, the solvents of the organic inks and the quantum dot inks may be organic solvents. For example, the solvents may include one or more independently selected from propylene glycol methyl ether acetate (PGMEA), dipropylene glycol n-propyl ether (DGPE), and triethylene glycol n-butyl ether (TGBE). Configurations or compositions of the solvents of the organic light emitting layers OEL32, OEL42, etc., and the quantum dot light emitting layers QEL41, etc., may be different from each other.

For example, there may be a problem that a drying characteristic of the organic ink and the quantum dot ink are different. For example, a coffee-ring effect that occurs during a process in which the solvent of the inks is dried may be a problem. The coffee-ring effect refers to a phenomenon in which particles are drawn to an edge portion of a droplet according to a difference in an evaporation speed for each portion of the droplet when the solvent is dried.

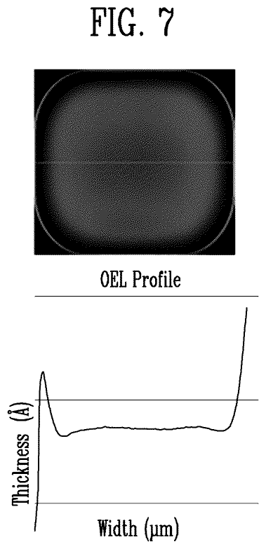

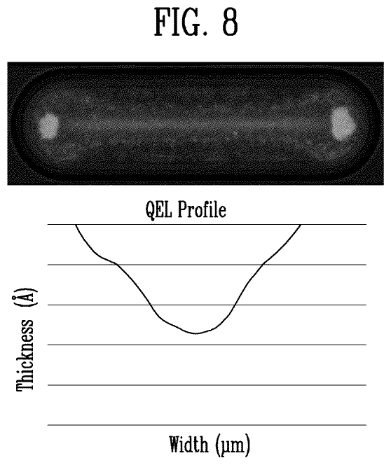

Referring to FIG. 7, the organic ink including the organic materials dissolved in the solvent may have a relatively uniform thickness after drying. For example, referring to FIG. 8, the quantum dot ink including the quantum dot compound that is not dissolved in the solvent has a relatively non-uniform thickness after drying. For example, when the evaporation speed of the droplet varies, a non-uniform distribution of the quantum dot compounds may become more severe. The non-uniform distribution of the quantum dot compounds may adversely affect display quality. Therefore, a drying speed of the quantum dot inks may be required to be maintained as constant as possible.

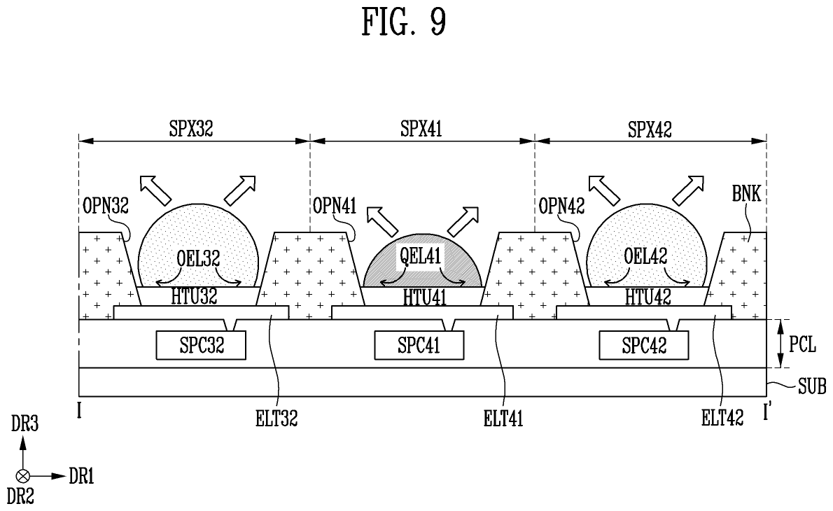

Referring to FIG. 9, the organic light emitting layers OEL32, OEL42, etc., and the quantum dot light emitting layers QEL41, etc., may be formed through an inkjet printing process. According to an embodiment, an inkjet printer including a nozzle formed to discharge fluid may be used so that the inkjet printing process may be performed. The inkjet printer may discharge the organic inks corresponding to the organic light emitting layers OEL32, OEL42, etc., and may discharge the quantum dot inks corresponding to the quantum dot light emitting layers QEL41, etc. For example, a solvent amount of the organic ink may be greater than or equal to a solvent amount of the quantum dot ink.

For example, after discharge of the organic ink and the quantum dot ink is completed, the organic ink and the quantum dot ink may begin to be dried simultaneously. For example, a boiling point of the solvent of the organic ink and the quantum dot ink may be set within a range of 200 degrees Celsius or more and 350 degrees Celsius or less. For example, drying may be performed in a vacuum state using a pump, and a heat source used for drying may have a temperature equal to or greater than room temperature and equal to or less than 100 degrees Celsius.

When the solvent amount of the organic ink is greater than the solvent amount of the quantum dot ink, drying of the quantum dot ink may be completed first, and then drying of the organic ink may be completed sequentially. In another example, when the solvent amount of the organic ink is the same as the solvent amount of the quantum dot ink, drying of the quantum dot ink and drying of the organic ink may be completed simultaneously. Therefore, the evaporation speed of the quantum dot ink may be maintained constant from a dry start time point to a dry completion time point. Therefore, the quantum dot compounds included in the quantum dot ink may be uniformly disposed.

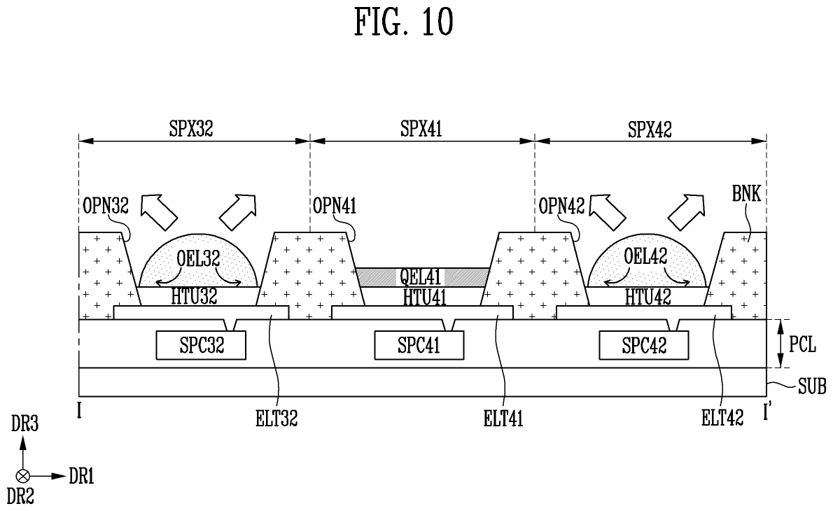

Referring to FIG. 10, the evaporation speed of the organic ink may increase after the dry completion time point of the quantum dot ink. However, since the organic materials are relatively less affected by a difference in the evaporation speeds, the organic materials may also be uniformly disposed.

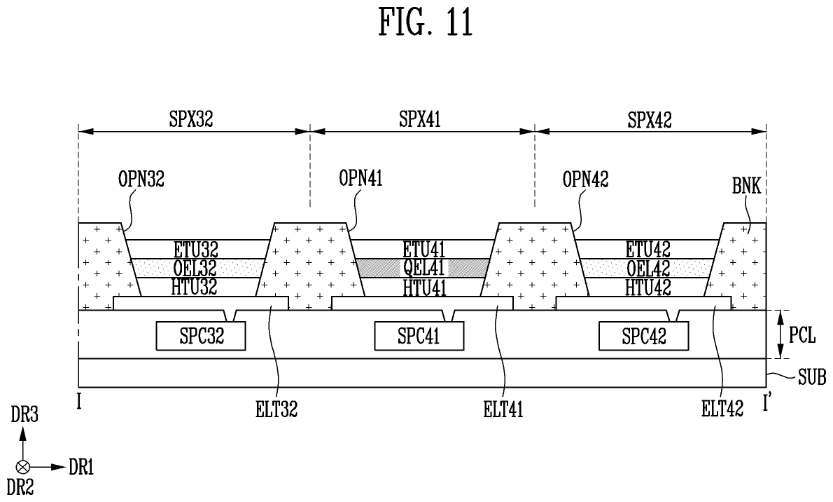

Referring to FIG. 11, in spite of a difference of the solvent amount, an amount of the organic materials of the organic ink and an amount of the quantum dot compounds of the quantum dot ink may be set so that the thickness of the quantum dot light emitting layers QEL41, etc., and the thickness of the organic light emitting layers OEL32, OEL42, etc., may be the same after drying completion.

After drying completion of the organic light emitting layers OEL32, OEL42, etc., and the quantum dot light emitting layers QEL41, etc., the electron transport layers ETU32, ETU41, ETU42, etc., may be formed on the organic light emitting layers OEL32, OEL42, etc., and the quantum dot light emitting layers QEL41, etc. The electron transport layers ETU32, ETU41, ETU42, etc., may be formed by various methods such as vacuum deposition, spin coating, casting, Langmuir-Blodgett (LB), inkjet printing, laser printing, and laser induced thermal imaging (LITI).

Thereafter, the cathode electrode ELT2 may be formed on the electron transport layers ETU32, ETU41, ETU42, etc., and the bank BNK (refer to FIG. 5).

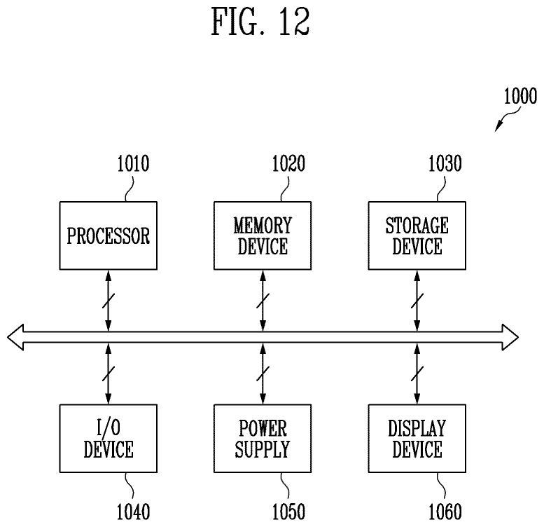

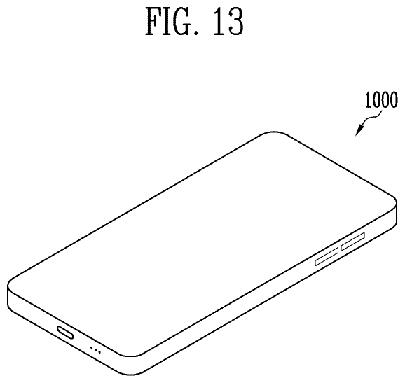

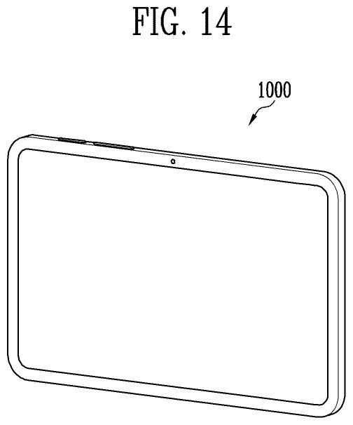

FIG. 12 is a schematic block diagram illustrating an electronic device 1000 including a display device in accordance with an embodiment. FIG. 13 is a schematic diagram illustrating an example where the electronic device 1000 of FIG. 12 is a smartphone. FIG. 14 is a schematic diagram illustrating an example where the electronic device 1000 of FIG. 12 is a tablet computer.

Referring to FIGS. 12 to 14, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 13, the electronic device 1000 may be a smartphone. In an embodiment, as illustrated in FIG. 14, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may be a microprocessor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to control signals or data from the processor 1010. The display device 1060 may be connected to other components through the buses or other communication links.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
organic light emitting elements each including an organic light emitting layer; and
quantum dot light emitting elements each including a quantum dot light emitting layer, wherein
the organic light emitting elements and the quantum dot light emitting elements are positioned in a same layer, and
each of the quantum dot light emitting elements is surrounded by adjacent organic light emitting elements.

2. The display device of claim 1, wherein distances between each of the quantum dot light emitting elements and the adjacent organic light emitting elements are shorter than distances between each of the quantum dot light emitting elements and adjacent quantum dot light emitting elements.

3. The display device of claim 1, wherein
the quantum dot light emitting elements include first quantum dot light emitting elements that emit light of a first color and second quantum dot light emitting elements that emit light of a second color,
the organic light emitting elements are formed to emit light of a third color, and
the first color, the second color, and the third color are different colors from each other.

4. The display device of claim 1, wherein a number of quantum dot light emitting elements and a number of organic light emitting elements are same as each other.

5. The display device of claim 1, wherein
each of the organic light emitting elements and each of the quantum dot light emitting elements include independent anode electrodes, and
the organic light emitting elements and the quantum dot light emitting elements include a common cathode electrode.

6. The display device of claim 5, further comprising:
a bank including openings exposing the anode electrodes.

7. The display device of claim 1, wherein
the quantum dot light emitting layer includes a quantum dot compound, and
the organic light emitting layer includes an organic material.

8. A method of manufacturing a display device, the method comprising:
forming anode electrodes of organic light emitting elements and quantum dot light emitting elements;
forming a bank including openings exposing the anode electrodes;
forming light emitting members in each of the openings; and
forming a cathode electrode to cover the light emitting members, wherein
each of the light emitting members of the organic light emitting elements includes an organic light emitting layer,
each of the light emitting members of the quantum dot light emitting elements includes a quantum dot light emitting layer, and
each of the quantum dot light emitting elements is surrounded by adjacent organic light emitting elements.

9. The method of claim 8, wherein the forming of the light emitting members comprises:
discharging an organic ink corresponding to the organic light emitting layer; and
discharging a quantum dot ink corresponding to the quantum dot light emitting layer, and
a solvent amount of the organic ink is greater than or equal to a solvent amount of the quantum dot ink.

10. The method of claim 9, wherein the forming of the light emitting members further comprises starting to dry the organic ink and the quantum dot ink simultaneously after discharge of the organic ink and the quantum dot ink is ended.

11. The method of claim 10, wherein after the drying of the quantum dot ink is completed, the drying of the organic ink is completed.

12. The method of claim 8, wherein distances between each of the quantum dot light emitting elements and the adjacent organic light emitting elements are shorter than distances between each of the quantum dot light emitting elements and adjacent quantum dot light emitting elements.

13. The method of claim 8, wherein
the quantum dot light emitting elements include first quantum dot light emitting elements that emit light of a first color and second quantum dot light emitting elements that emit light of a second color,
the organic light emitting elements are formed to emit light of a third color, and
the first color, the second color, and the third color are different colors from each other.

14. The method of claim 8, wherein a number of quantum dot light emitting elements and a number of organic light emitting elements are same as each other.

15. A method of manufacturing a display device, the method comprising:
forming anode electrodes of organic light emitting elements and quantum dot light emitting elements;
forming a bank including openings exposing the anode electrodes;
forming light emitting members in each of the openings; and
forming a cathode electrode to cover the light emitting members, wherein
each of the light emitting members of the organic light emitting elements includes an organic light emitting layer,
each of the light emitting members of the quantum dot light emitting elements includes a quantum dot light emitting layer,
the forming of the light emitting members comprises:
discharging an organic ink corresponding to the organic light emitting layer; and
discharging a quantum dot ink corresponding to the quantum dot light emitting layer, and
a solvent amount of the organic ink is greater than or equal to a solvent amount of the quantum dot ink.

16. The method of claim 15, wherein each of the quantum dot light emitting elements is surrounded by adjacent organic light emitting elements.

17. The method of claim 15, wherein the forming of the light emitting members further comprises starting to dry the organic ink and the quantum dot ink simultaneously after the discharging of the organic ink and the quantum dot ink is ended.

18. The method of claim 17, wherein after the drying of the quantum dot ink is completed, the drying of the organic ink is completed.

19. The method of claim 16, wherein distances between each of the quantum dot light emitting elements and the adjacent organic light emitting elements are shorter than distances between each of the quantum dot light emitting elements and adjacent quantum dot light emitting elements.

20. The method of claim 15, wherein
the quantum dot light emitting elements include first quantum dot light emitting elements that emit light of a first color and second quantum dot light emitting elements that emit light of a second color,
the organic light emitting elements are formed to emit light of a third color, and
the first color, the second color, and the third color are different colors from each other.

21. An electronic device comprising:
a processor to provide input image data; and
a display device to display an image based on the input image data, the display device comprising:
organic light emitting elements each including an organic light emitting layer; and
quantum dot light emitting elements each including a quantum dot light emitting layer, wherein
the organic light emitting elements and the quantum dot light emitting elements are positioned in a same layer, and
each of the quantum dot light emitting elements is surrounded by adjacent organic light emitting elements.
